(19) United States
(12) Patent Application Publication
(10) Pub. No.: US 2012/0037991 A1
(43) Pub. Date: Feb. 16, 2012

(54) Silicon on Insulator Field Effect Device

(75) Inventors: Dechao Guo, Wappingers Falls, NY (US); Zhen Zhang, Ossining, NY (US)

(73) Assignee: INTERNATIONAL BUSINESS MACHINES CORPORATION, Armonk, NY (US)

(21) Appl. No.: 12/857,022

(22) Filed: Aug. 16, 2010

(51) Int. Cl. H01L 29/786; H01L 21/336

(52) U.S. Cl. 257/347; 438/151; 257/E21.415; 257/E29.286

(57) ABSTRACT

A field effect transistor device includes a silicon on insulator (SOI) body portion disposed on a buried oxide (BOX) substrate, a gate stack portion disposed on the SOI body portion, a first silicide material disposed on the BOX substrate arranged adjacent to the gate stack portion, a second silicide material arranged on the first silicide material, a source region including a portion of the first silicide material and the second silicide material, and a drain region including a portion of the first silicide material and the second silicide material.

### FIELD OF INVENTION

The present invention relates to semiconductor field effect transistors (FET), and particularly to extremely thin silicon on insulator (ETSOI) field effect transistors.

### DESCRIPTION OF RELATED ART

Planar field effect transistor (FET) devices include a gate stack disposed on a channel region of a substrate and source and drain regions disposed adjacent to the gate stack. In extremely thin silicon on insulator devices, the channel regions of the devices are typically less than 5 nm in thickness. An ETSOI device may be fabricated to include a Schottky junction in the source and drain regions of the device. The Shottky junction typically results in a low junction voltage. The low junction voltage increases the switching speed of the device and assists in preventing oversaturation.

### BRIEF SUMMARY

In one aspect of the present invention, a method for fabricating a field effect transistor device includes forming a silicon on insulator (SOI) layer on a buried oxide (BOX) layer, forming a dummy gate stack portion on the SOI layer, forming a spacer adjacent to the dummy gate stack portion, forming a first silicide material on exposed portions of the SOI layer, epitaxially growing a silicon material on the first silicide material, forming a second silicide material on the epitaxially grown silicide material, forming a liner layer over the second silicide material and the dummy gate stack, removing the dummy gate stack to form a cavity defined by the spacer and an exposed portion of the SOI layer, removing a portion of the exposed portion of the SOI layer to reduce the thickness of the exposed portion of the SOI layer, and forming a gate stack on the exposed portion of the SOI layer.

In another aspect of the present invention, a field effect transistor device includes a silicon on insulator (SOI) body portion disposed on a buried oxide (BOX) substrate, a gate stack portion disposed on the SOI body portion, a first silicide material disposed on the BOX substrate arranged adjacent to the gate stack portion, a second silicide material arranged on the first silicide material, a source region including a portion of the first silicide material and the second silicide material, and a drain region including a portion of the first silicide material and the second silicide material.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 illustrates a side cut-away view of an exemplary embodiment of a field effect transistor (FET) device.

FIGS. 2-10 illustrate a side cut-away view of an exemplary method for fabricating a device similar to the device of FIG. 1, in which:

FIG. 2 illustrates the formation of a dummy gate stack;

FIG. 3 illustrates the formation of a spacer portion;

FIG. 4 illustrates the formation of a first silicide portion;

FIG. 5 illustrates the formation of a second silicide portion;

FIG. 6 illustrates the formation of a liner layer;

FIG. 7 illustrates the resultant structure following the removal of the liner layer;

FIG. 8 illustrates the removal of portions of a silicon on insulator portion;

FIG. 9 illustrates the formation of an insulator spacer portion; and

FIG. 10 illustrates the resultant device following the formation of a dielectric layer.

### DETAILED DESCRIPTION

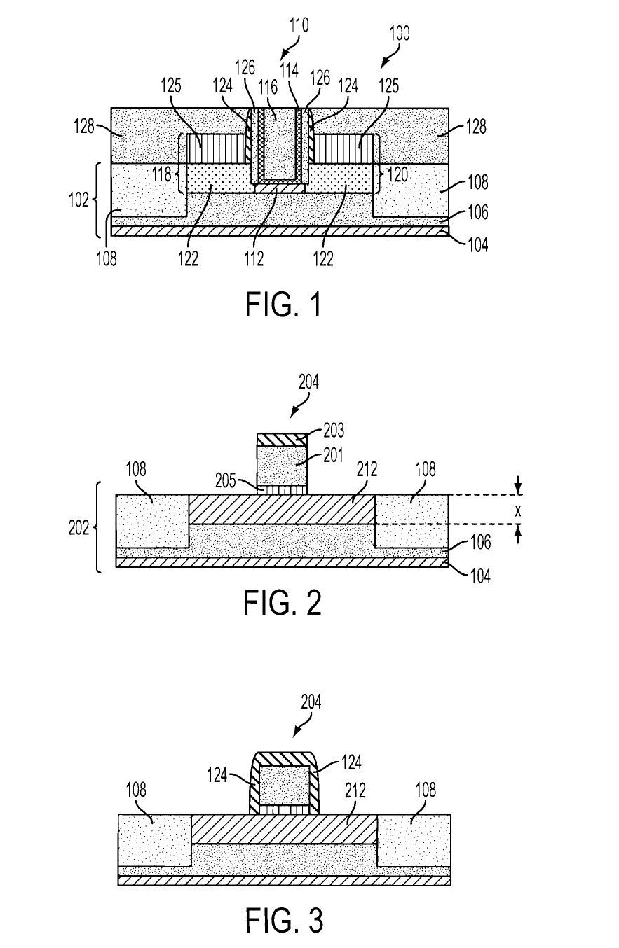

FIG. 1 illustrates a side cut-away view of an exemplary embodiment of a field effect transistor (FET) device 100. The device 100 includes a substrate portion 102 that includes a silicon region 104, a buried oxide (BOX) region 106 disposed on the silicon region 104, and a silicon trench isolation (STI) region 108 in the BOX region 106. The device 100 includes a gate stack portion 110. The gate stack portion 110 is disposed on a silicon on insulator (SOI) portion (body portion) 112 that is disposed on the BOX region 106. In the illustrated embodiment, the gate stack portion 110 includes a layer 114 that may include, for example, a high-K layer or a dielectric material layer and a metallic gate material 116 disposed on the layer 114.

The device 100 includes a source region 118 and a drain region 120 that each include a first silicide portion 122 disposed on the BOX region 106 and a second silicide portion 125 disposed on the first silicide portion 122. The device 100 may include a first spacer portion 126 disposed adjacent to the gate stack portion 110 and a second spacer portion 124 disposed adjacent to the first spacer portion 126. The first spacer portion 124 may include an insulator material such as, for example, a silicon dioxide material. The second spacer portion 124 may include, for example, a nitride or an oxide material. A stress liner portion 128 is disposed on the second silicide portion 124 and the STI region 108. The stress liner portion 128 may include, for example, a nitride or oxide material.

The device 100 includes a thin SOI portion 112 having a body thickness of, for example, less than 5 nm and relatively thick source and drain regions 118 and 120. The source and drain regions 118 and 120 each include two silicide portions that improve the yield of the source and drain regions 118 and 120 and improves the uniformity of the device.

FIGS. 2-10 illustrate a side cut-away view of an exemplary method for fabricating a device similar to the device 100 described above. In this regard, referring to FIG. 2, a dummy gate stack portion 204 is formed on a substrate 202. The substrate 202 includes a silicon region 104 and a BOX region 106 formed on the silicon region 104, and a silicon on insulator (SOI) portion 212 formed on the BOX region 105. The SOI portion 212 includes a thickness (x) that may, for example, range from approximately 10-20 nm. The dummy gate stack portion 204 is formed on the SOI portion 212 and includes, for example, an insulator portion 205, a polysilicon portion 201 and a capping layer 203 that may include, for example, a nitride or oxide material. The dummy gate stack may be formed by a suitable deposition and patterning process such as, for example, a chemical vapor deposition (CVD) process or a plasma-enhanced chemical vapor deposition (PECVD) process followed by a patterning and etching process such as a reactive ion etching process (RIE).

FIG. 3 illustrates the resultant structure following the formation of a spacer portion 124 on the SOI portion 212 adjacent to the dummy gate stack portion 203. The spacer portion 124 may be formed from, for example, a silicon nitride (SiN) material.

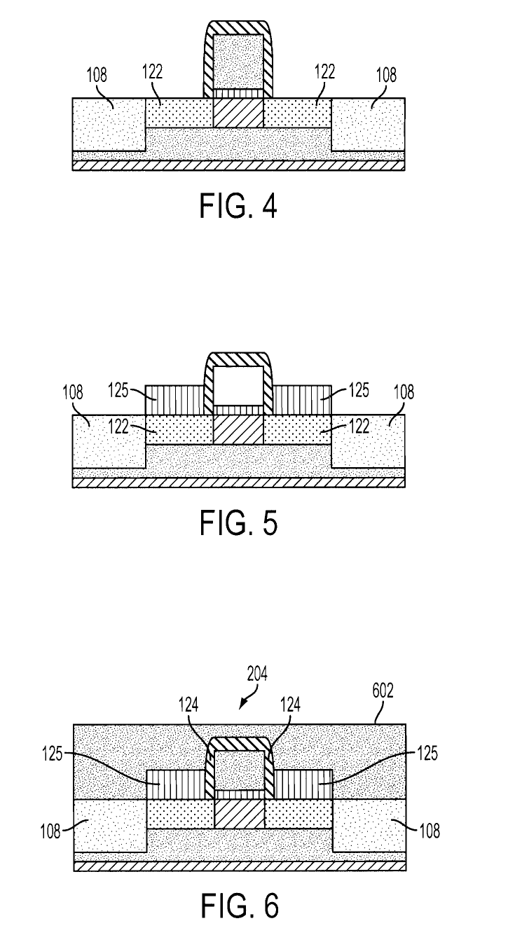

FIG. 4 illustrates the formation of a first silicide portion 122 in exposed portions of the SOI portion 212. For example, the first silicide portion 122 may be formed by blanket depositing a metal such as Ni, Pt, Co, Ti, Pd, Er, Yb or combinations of such metals on the SOI portion 212; reacting the deposited metal with silicon by thermal annealing to form metal silicides; and selectively wet etching to remove unreacted metal. Alternatively, a silicide may be formed by blanket depositing metal such as Ni, Pt, Co, Ti, Pd, Er, Yb or combinations of such metals on the SOI portion 212; removing the portions of the deposited metal by selective wet etching such that a portion of a metal-silicon intermix layer remains in regions where the metal directly contacts the silicon; and transferring the intermixed layer to metal silicides by thermal annealing.

FIG. 5 illustrates the formation of a second silicide portion 125 on the first silicide portion 122. The second silicide portion 125 may be formed by epitaxially growing a silicon material on the exposed portions of first silicide portion 122. The second silicide portion 125 may be doped with ions during the epitaxial growth process (in-situ) or following the epitaxial growth process using an ion implantation and annealing process. Once the doped silicon material is formed, a silicide material is formed on the doped silicon material resulting in the illustrated second silicide portion 125.

FIG. 6 illustrates the formation of a liner layer 128. The liner layer is formed over the exposed portions of the STI region 108, the second silicide portion 125, the spacer portion 124, and the dummy stack portion 204. The liner layer 128 may be formed from, for example, a nitride or oxide material.

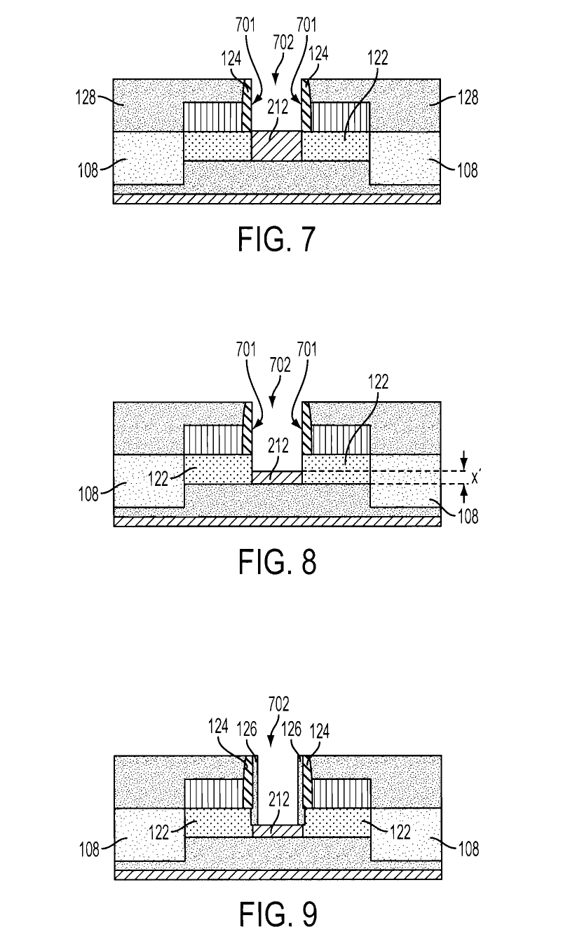

FIG. 7 illustrates the resultant structure following the removal of portions of the liner layer 128 and the dummy stack portion 204 (of FIG. 6). In this regard, the liner layer 128 is thinned using, for example, a chemical mechanical polishing (CMP) process that exposes the polysilicon portion 201. The polysilicon portion 201 may be removed using a suitable etching process such as, for example a RIE process or a wet etch process that exposes insulator portion 205. The underlying insulator portion 205 may be removed using a suitable etching process such as, for example SC1 wet etching that exposes a portion of the SOI portion 212. The removal of the dummy stack portion 204 forms a cavity 702 that is defined by the spacer portion 124 and the SOI portion 212 and includes sidewalls 701.

FIG. 8 illustrates the resultant structure following the removal of portions of the SOI portion 212 that thins the exposed SOI portion 212. The SOI portion 212 may be thinned using an etching process such as RIE. The resultant SOI portion 212 is thinned such that the SOI portion 212 has a thickness of (x′) where x′ is approximately 5 nm. The thinning of the SOI portion 212 may expose portions of the first silicide portion 122.

FIG. 9 illustrates the formation of an insulator spacer portion 126 that may include, for example a low-K insulating material such as silicon dioxide, or SiCOH The spacer portion 126 is formed along the sidewalls 701 of the cavity 702 and insulates exposed portions of the first silicide portion 122.

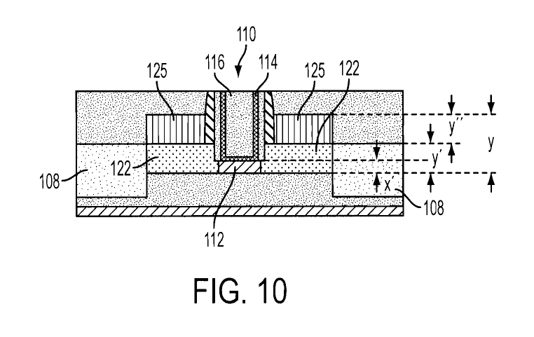

FIG. 10 illustrates the resultant device 100 following the formation of a dielectric layer 114 in the cavity 702 (of FIG. 9) and the filling of the cavity 702 with a metallic gate material 116. In the illustrated embodiment, the first silicide portion 122 has a thickness (y′) and the second silicide portion 125 has a thickness (y″) The first silicide portion and the second silicide portion 125 have a combined thickness of (y) where y=y′+y″. In the illustrated embodiment y>x′ and y′ may be greater than x′.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A method for fabricating a field effect transistor device, the method including:
forming a silicon on insulator (SOI) layer on a buried oxide (BOX) layer;
forming a dummy gate stack portion on the SOI layer;
forming a spacer adjacent to the dummy gate stack portion;
forming a first silicide material on exposed portions of the SOI layer;
epitaxially growing a silicon material on the first silicide material;
forming a second silicide material on the epitaxially grown silicide material;
forming a liner layer over the second silicide material and the dummy gate stack;
removing the dummy gate stack to form a cavity defined by the spacer and an exposed portion of the SOI layer;
removing a portion of the exposed portion of the SOI layer to reduce the thickness of the exposed portion of the SOI layer; and
forming a gate stack on the exposed portion of the SOI layer.

2. The method of claim 1, wherein the method further includes forming an insulator layer on sidewalls of the cavity prior to forming the gate stack.

3. The method of claim 2, wherein the insulator layer includes a silicon dioxide material.

4. The method of claim 1, wherein the forming a gate stack on the exposed portion of the SOI layer includes:
forming a high-K layer on the exposed portion of the SOI layer; and
forming a metallic gate material on the high-K layer.

5. The method of claim 1, wherein the method further includes doping the epitaxially grown silicon material with ions during the epitaxial growth process.

6. The method of claim 1, wherein the method further includes implanting ions in the epitaxially grown silicon material prior to forming the second silicide material.

7. The method of claim 1, wherein the portion of the exposed portion of the SOI layer is removed by an etching process.

8. The method of claim 7, wherein the exposed portion of the SOI layer has a resultant thickness of less than 5 nanometers following the etching process.

9. The method of claim 1, wherein the thickness of the exposed portion of the SOI layer is less than a thickness of the first silicide material.

10. The method of claim 1, wherein the dummy gate stack is formed by:
forming a layer of polysilicon material on the SOI layer;
forming a capping layer on the polysilicon material; and
etching to remove portions of the polysilicon material and the capping layer to pattern the dummy gate stack.

11. The method of claim 1, wherein the SOI layer is formed with a thickness of approximately 10-20 nm.

12. The method of claim 1, wherein the method further includes removing portions of the liner layer to expose the dummy gate stack prior to removing the dummy gate stack.

13. The method of claim 3, wherein the BOX substrate layer is disposed on a silicon substrate.

14. A field effect transistor device comprising:
a silicon on insulator (SOI) body portion disposed on a buried oxide (BOX) substrate;
a gate stack portion disposed on the SOI body portion;
a first silicide material disposed on the BOX substrate arranged adjacent to the gate stack portion;
a second silicide material arranged on the first silicide material;
a source region including a portion of the first silicide material and the second silicide material; and
a drain region including a portion of the first silicide material and the second silicide material.

15. The device of claim 1, wherein the gate stack portion is disposed in a cavity partially defined by the first silicide material and the SOI body portion.

16. The device of claim 15, wherein the cavity includes sidewalls lined with an insulator material.

17. The device of claim 1, wherein the second silicide material includes epitaxially grown silicon material.

18. The device of claim 17, wherein the epitaxially grown silicon material is doped with ions.

19. The device of claim 1, wherein the SOI body portion has a thickness of less than 5 nm.

20. The device of claim 1, wherein the first silicide material has a thickness greater than a thickness of the SOI body portion.
